(19) United States
(12) Patent Application Publication
(10) Pub. No.: US 2005/0225335 A1
(43) Pub. Date: Oct. 13, 2005

(54) Moisture detector

(76) Inventor: Leonard R. Filipkowski, Duluth, GA (US)

Correspondence Address: SMITH, GAMBRELL & RUSSELL, LLP, 1230 PEACHTREE STREET, N.E., SUITE 3100, PROMENADE II, ATLANTA, GA, 30309-3592, US

(21) Appl. No.: 10/822,948

(22) Filed: Apr. 13, 2004

(51) Int. Cl. H02P 1/04; H02P 3/00; G05B 5/00; H02P 7/00; H02H 7/08; G01R 27/08

(52) U.S. Cl. 324/696

(57) ABSTRACT

A moisture detector detects moisture in a closed environment. A microcontroller is connected to an elongated strip sensor, a spot sensor, or a combination of strip sensors and spot sensors. The elongated strip sensors have fabric substrate with parallel conductor strips. The spot sensors comprise point electrodes embedded in a substrate consisting of existing building material. The conductor strips and the point electrodes are connected to the microcontroller. The electrical resistance of the substrates vary based on the amount for moisture absorbed, and the microcontroller may be programmed to detect a threshold resistance indicative of the presence of moisture. Once moisture is detected, the microcontroller can provide various alarm functions and communication functions.

### FIELD OF THE INVENTION

The present invention relates to a method and system for detecting moisture in a closed environment, and more particularly relates to method and system for using a microcontroller connected to an elongated strip sensor, a single point spot sensor, or a combination of strip sensors and spot sensors to detect the presence of moisture in the closed environment.

### BACKGROUND OF THE INVENTION

The presence of moisture in a home or place of business may be the source of numerous problems. The presence of moisture may be the result of leaking plumbing, a leaking roof, or infiltration through a defective vapor barrier. The damage to a home or place of business as a result of the invasion of large quantities of water from leaking plumbing or a leaking roof is readily apparent. The damage that may result from the presence of small amounts of moisture may also be deleterious to the safety and health of the occupants of a home or place of business. Particularly, mold grows in the presence of moisture, and mold can produce an unhealthy environment for the occupants of a home or place of business.

Existing moisture detectors generally require expensive sensors that produce accurate outputs based on the existence of moisture at a particular location. Using such sensors to monitor a large space especially the space around all doors and windows and along baseboards would be prohibitively expense.

### SUMMARY OF THE INVENTION

The present invention provides a system and method for detecting moisture in a closed environment that uses a microcontroller connected to an elongated strip sensor, a spot sensor, or a combination of strip sensors and spot sensors to detect the presence of moisture in the closed environment. The invention provides a cost-effective means for monitoring the presence of moisture in various closed environments. The elongated strip sensors are flexible and can be fit around windows, doors, walls, plumbing points, showers and tubs, air conditioning units, appliances, and any other location where a moisture sensor is desired. The strip sensors use the electrical properties of a fabric material to provide a conductive path between strip conductors. The spot sensors utilize the electrical properties of existing building materials, such as dry wall, to provide a conductive path between embedded electrodes and thereby provide a moisture sensor at a particular localized point.

Because the strip sensors and spot sensors provide electrical responses that may vary based on the length and width of the strip sensor or the material and spacing of the embedded electrodes of the spot sensor, the microcontroller may be programmed to compensate for inaccuracies or other anomalies introduced by the particular configuration of the strip sensors or spot sensors. Further, the microcontroller can be designed to handle multiple separate strip sensors of various lengths in combinations with spot sensors. Because the microcontroller has the capability of multiple inputs for connection to various separate combinations of strip sensors and spot sensors, the microcontroller can determine the location of the moisture intrusion by identifying the sensor or group of sensors which has been activated by the intrusion of moisture.

The utilization of a microcontroller also provides a moisture detector system with a full functioning alarm system. For example, the microcontroller can be programmed simply to light a light emitting diode (LED) or to sound a horn if one of the sensors encounters moisture. In addition, the microcontroller can be programmed to contact a remote monitoring service by means of a direct wired connection, a wired network connection, a direct wireless connection, or a wireless network connection. Because the multiple input microcontroller in a moisture detector system can determine the location of the moisture intrusion, the microcontroller can communicate to the remote monitoring service not only the name and address for the home or place of business, but also the location of the moisture intrusion within the home or place of business. Further, the microcontroller can be connected to a plumbing shut off valve so that the water can be shut off in response to the presence of moisture in a particular location.

Each microcontroller can be programmed by a personal computer using the RS-232 protocol connected to the serial port. The program for the microcontroller can be stored on an onboard EEPROM along with any calibration values needed. The program can be set so that each sensor or group of sensors can be monitored individually with a pre-determined threshold value for that sensor or group of sensors.

In one embodiment of the presence invention, a strip sensor comprises a strip substrate made of water absorbing fabric such as non-treated polyester. Two conductors strips or wires are mounted on and separated by the sensor substrate fabric. The sensor fabric separating the two conductors wires acts as an insulator with high resistance when the fabric is dry. However, when moisture is absorbed by the sensor fabric, the resistance of the fabric will drop so that electric current can begin flowing between the two conductor wires. For a particular strip substrate comprising a particular material, having a particular length, and having particular separation between the conductor strips, a threshold value for resistance can be determined empirically, and the trigger point for the microcontroller set accordingly.

In another embodiment of the present invention, a spot sensor comprises two electrodes embedded in a spot substrate material, such as dry wall material or other building material, where moisture is to be monitored. The building material which forms the substrate of the spot detector must have high resistance when dry and reduced resistance in the presence of moisture. The electrical characteristics of the spot detector are also affected by the width of separation between the embedded electrodes. For a particular spot substrate comprising a particular material and having particular separation between the electrodes, a threshold value for resistance can be determined empirically, and the trigger point for the microcontroller set accordingly.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

The present invention, as defined in the claims, can be better understood with reference to the following drawings. The components within the drawings are not necessarily to scale relative to each other, emphasis instead being placed upon clearly illustrating the principles of the present invention.

FIG. 1 is a block diagram showing a microcontroller connected to a strip sensor in accordance with the present invention (moisture not present).

FIG. 2 is a block diagram showing a microcontroller connected to a strip sensor in accordance with the present invention (moisture present).

FIG. 3 is a schematic diagram of a strip sensor in accordance with the present invention.

FIG. 4 is a schematic diagram of a spot sensor in accordance with the present invention.

FIG. 5 is a flow chart for programming a microcontroller to monitor moisture sensors in accordance with the present invention.

FIG. 6 is a block diagram of a moisture detection system with multiple strip sensors, multiple spot sensors, and combinations of strip sensors and spot sensors in accordance with the present invention.

### DETAILED DESCRIPTION OF THE EMBODIMENTS OF THE INVENTION

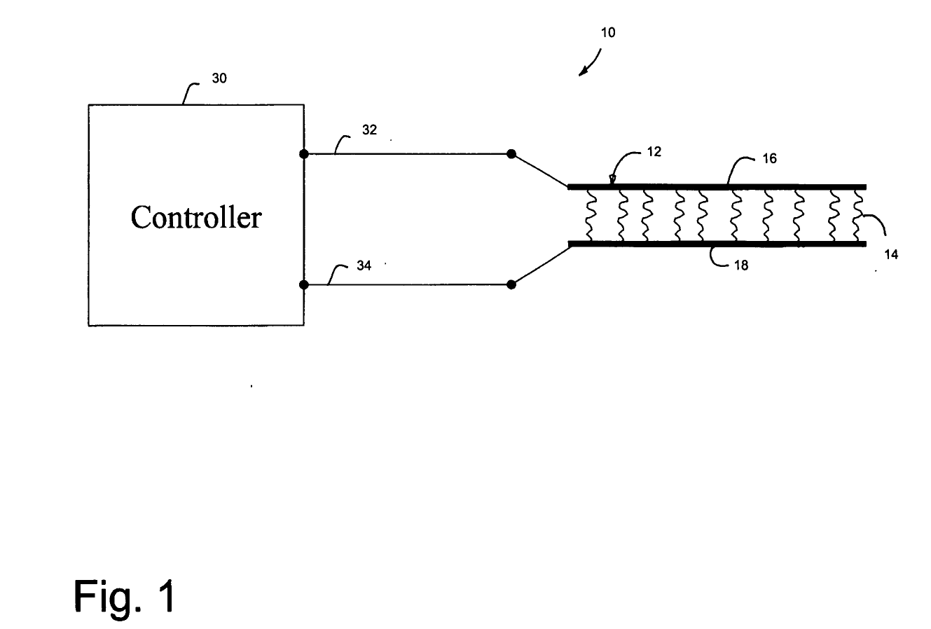

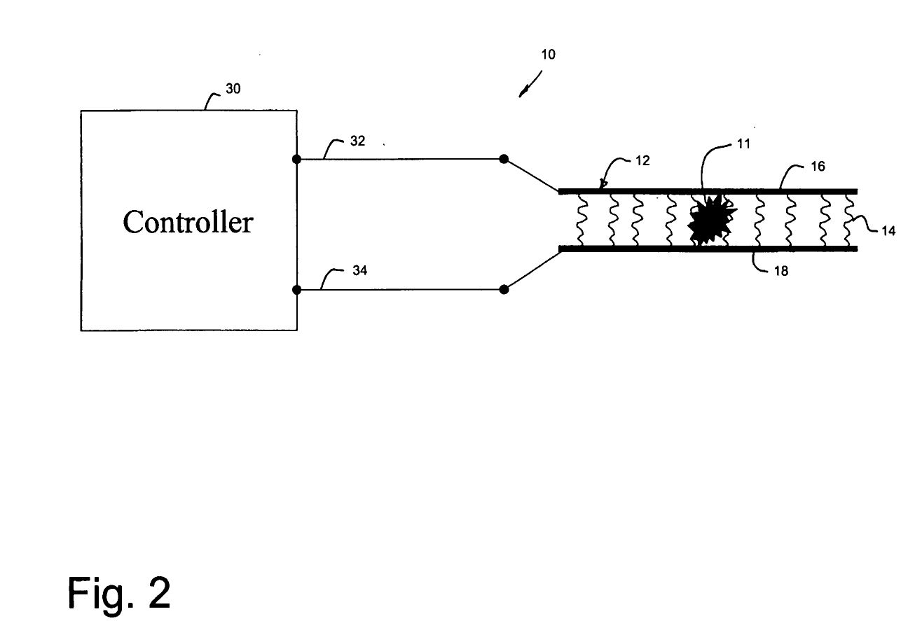

Turning to FIGS. 1 and 2, a moisture detector 10 is shown comprising a microcontroller 30 and a strip sensor 12. In FIG. 1, the strip sensor 12 is connected to microcontroller 30 by means of inputs 32 and 34. When the strip sensor 12 shown in FIG. 1 is dry, the resistance between inputs 32 and 34 is high, and based on that high resistance, the microcontroller 30 recognizes that there is no moisture present at the strip sensor 12. Alternatively, in FIG. 2, moisture, such as a drop of water 11, is present at the strip sensor 12. As will be explained in greater detail, the presence of moisture on strip center 12 causes the resistance across inputs 32 and 34 to decrease. The microcontroller 30 recognizes the decrease in resistance at inputs 32 and 34, and produces an alarm indicating the presence of moisture at the location of the strip sensor 12.

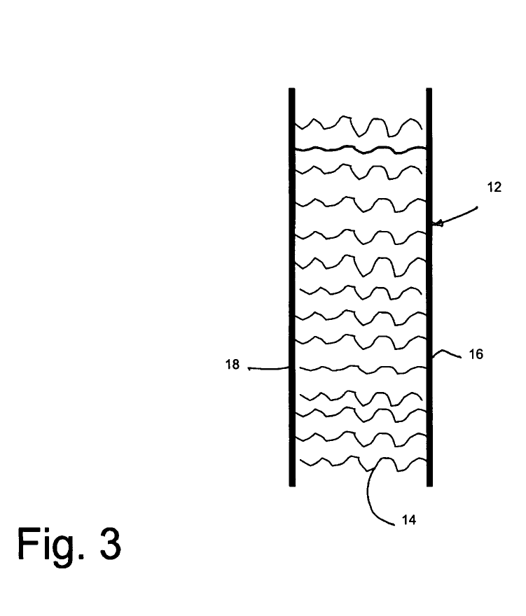

A detailed view of the strip sensor 12 is shown in FIG. 3. The strip sensor 12, in the form of an elongated ribbon, comprises a strip substrate 14 on which are mounted conductor strips 16 and 18. The conductor strips 16 and 18 extend essentially parallel along the length of the strip sensor 12. The conductor strips 16 and 18 on the strip substrate 14 are separated by a predetermined distance. The conductor strips 16 and 18 comprise conductive metal strips, such as wire, metal foil, or other suitable conductor.

The strip substrate 14 may constitute a variety of materials which exhibit the characteristic of having a high electrical resistance in the absence of moisture and a reduced electrical resistance when moisture is present on the strip substrate 14. The strip substrate 14 in one embodiment of the invention is a water absorbing fabric such as untreated polyester. A particularly useful untreated polyester fabric is available from McMaster Carr, 6100 Fulton Industrial Blvd., Atlanta, Ga. 30336-2852, as a plain weave polyester webbing. That untreated polyester fabric has a dry resistance of greater than 6 megohms and a moisture saturated resistance of less than 5 megohms. The resistance of the fabric changes in a linear fashion based on volume of liquid absorbed and the separation of the conductor strips 16 and 18. By adjusting the separation of the conductor strips 16 and 18, the time constant of the drop in resistance can be changed. Once the resistance of the fabric strip substrate 14 between the conductor strips for 16 and 18 drops below about 5 megohms, that resistance at the inputs 32 and 34 of the microcontroller 30 causes the analog to digital converter of the microcontroller 30 to begin registering the presence of moisture. As more moisture is absorbed by the fabric strip substrate 14, the resistance of the fabric strip substrate 14 continues dropping until the resistance reaches almost 0 ohms thereby allowing current to flow from one conductor strips 16 through the saturated fabric to the other conductor strip 18 driven by 5 volts of potential between the conductor strips 16 and 18. The microcontroller 30 can thus be programmed to recognize the progressive drop in resistance from a dry fabric to a fully saturated fabric and produce alarms accordingly.

For the strip sensor 12 for use with the microcontroller 30, other suitable strip substrate materials include Nylon, polypropylene, and cotton or muslin having a dry resistance of greater than 6 megohms and a wet resistance of less than 5 megohms. By using a microcontroller with a different input impedance, the wet and dry resistance of the strip substrate 14 may be adjusted accordingly.

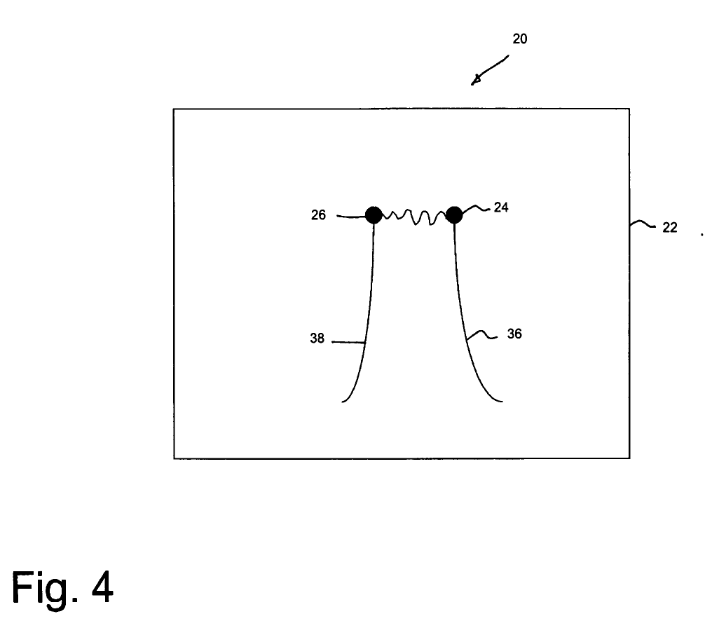

An alternative moisture sensor is a spot sensor 20 shown in FIG. 4. The spot sensor 20 comprises a spot substrate 22 in which electrodes 24 and 26 are embedded. The electrodes 24 and 26 are connected via wires 36 and 38 to the inputs 32 and 34 of the microcontroller 30. The electrodes 24 and 26 comprise metal pins or the like embedded directly into the spot substrate 22. In one embodiment of the spot sensor 20, the spot substrate 22 is dry wall material that is used to construct a wall where moisture detection is desired. For ordinary dry wall such as that provided by US Gypsum, Georgia Pacific, and for an electrode separation of about 1 inch the dry resistance across the electrodes 24 and 26 is greater than 6 megohms. When the spot substrate 22 is saturated with moisture, the resistance across the electrodes 24 and 26 is reduced to less than 5 megohms. The resistance of the spot substrate 22 changes in a linear fashion based on volume of liquid absorbed and the separation of the electrodes 24 and 26. By adjusting the separation of the electrodes 24 and 26, the time constant of the drop in resistance can be changed. Once the resistance of the spot substrate 22 between the electrodes 24 and 26 drops below about 5 megohms, that resistance at the inputs 32 and 34 of the microcontroller 30 causes the analog to digital converter of the microcontroller 30 to begin registering the presence of moisture. As more moisture is absorbed by the spot substrate 22, the resistance of the spot substrate 22 continues dropping until the resistance reaches almost 0 ohms thereby allowing current to flow from one electrode 24 through the saturated substrate to the other electrode 26 driven by 5 volts of potential between the electrodes 24 and 26. The microcontroller 30 can thus be programmed to recognize the progressive drop in resistance from a dry substrate to a fully saturated substrate and produce alarms accordingly.

In use, the strip sensor 12 provides the advantage of monitoring an extended area of an enclosed space. The strip sensor 12 can be mounted around a window or door or along a baseboard to sense the presence of moisture at any point around the window or door or along the baseboard. By contrast, the spot sensor 20 can only monitor the area directly adjacent the space between the electrodes 24 and 26.

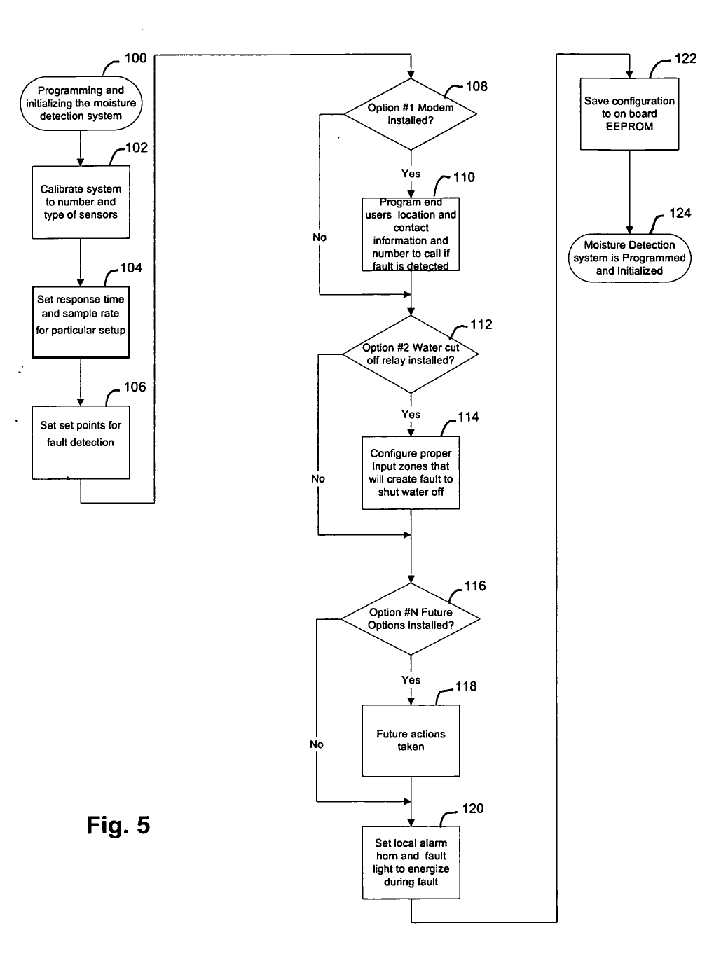

The microcontroller 30 is connected to the strip sensor 12 or the spot sensor 20 and monitors the resistance of those sensors to determine whether or not moisture is present. Because the strip sensor 12 and a spot sensor 20 may be made of different substrate materials, the resistance range may vary from sensor to sensor. Therefore, the microcontroller 30 is programmed to identify the appropriate trigger level for each of the sensors connected to the microcontroller 30. Moreover, in order to minimize false triggers, the microcontroller 30 has the ability to monitor the resistance of the sensors over time and create a sensor profile. The sensor profile provides a comparison baseline for determining whether the sensor has actually encountered moisture or whether the sensor is operating within the acceptable resistance range for different levels of relative humidity. FIG. 5 is a flow chart showing the method employed for setting up the microcontroller 30 for monitoring the resistance of the sensors connected to the microcontroller 30. In that regard, the program method employed to set up the microcontroller 30 begins at step 100 and proceeds to step 102 where the trigger level for the microcontroller 30 is calibrated to the number and type of sensors connected to the microcontroller 30. The calibration at step 102 is based on the empirically determined resistance values of the strip sensors and a spot sensors connected to the microcontroller 30. At step 104, the response time and sampling rate for the particular sensor configuration is set within the microcontroller 30. Again the response time and sampling rate for the sensor configuration is empirically determined prior to setting the microcontroller 30. At step 106, the set points for fault detection by the microcontroller 30 are set.

The set up method then proceeds to step 108 where the microcontroller 30 determines whether a modem is connected to its output. If a modem is connected the set up procedure continues to step 110 where the user location and the call contact information is stored so that upon the detection of a fault (the presence of moisture), the modem will dial the security company and transmit the necessary information to identify the location where the moisture sensors are located. If the modem is not present at step 108, the method proceeds to step 112 where the microcontroller 30 determines whether a water cut off relay is installed. If a water cut off relay is installed, the setup program moves to step 114 where the microcontroller 30 is configured to activate one or more water cut off relays depending on the location of the sensed fault. If there is no water cut off relay, the program moves from step 112 to step 116 which represents a generic configuration for additional future installation options (step 118) for communication in the presence of a moisture fault or initiation of a particular remedial action in the presence of a moisture fault.

From step 118, the set up procedure moves to step 120 where the local alarms or warning light is configured for activation in the presence of a detected moisture fault. From step 120, the set up procedure moves to step 122 where the configuration for the system is set within the storage medium of the microcontroller 30. Once the programming has been stored at step 122, the microcontroller 30 is initialized and ready to begin monitoring the sensors for the presence of moisture.

The program for the microcontroller 30 can be implemented in hardware, software, firmware, or a combination thereof. In the preferred embodiment(s), the program for the microcontroller 30 is implemented in software or firmware that is stored in a memory and that is executed by a suitable instruction execution system in the microcontroller 30. If the program is implemented in hardware, as in an alternative embodiment, the program can be implemented with any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

The program for the microcontroller 30, which comprises an ordered listing of executable instructions for implementing logical functions, can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical).

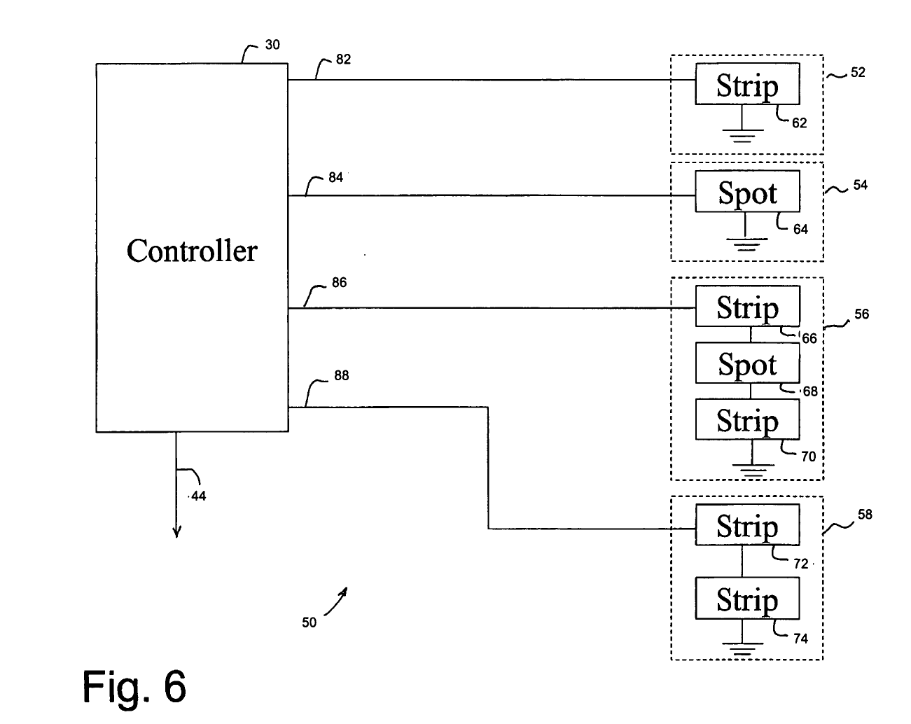

FIG. 6 is a block diagram of a moisture detection system 50 utilizing multiple sensors organized into zones for the purpose of identifying the location of an invasion of moisture in a closed environment. The moisture detection system 50 comprises the microcontroller 30 having multiple separate inputs to, shown illustratively as 82, 84, 86, and 88. In addition, the microcontroller 30 has an output 44 which can be used to communicate an alarm condition in various well known ways. For example, the microcontroller can be programmed simply to light a light emitting diode (LED) or to sound a horn if one of the sensors encounters moisture. In addition, the microcontroller can be programmed to contact a remote monitoring service by means of a direct wired connection, a wired network connection, a direct wireless connection, or a wireless network connection. Because the microcontroller 30 in the moisture detector system 50 can determine of the location of the moisture intrusion, as will be more fully described below, the microcontroller 30 can communicate to the remote monitoring service not only the name and address for the home or place of business, but also the location of the moisture intrusion within the home or place of business. Further, the microcontroller can be connected to a plumbing shut off the valve so that the water can be shut off in response to the presence of moisture in a particular location.

Each of the separate inputs 82, 84, 86, and 88 is connected to one or more sensors in each of zones 52, 54, 56, and 58 respectively. While many configurations of sensors and zones is contemplated by the present invention, the moisture detection system 50 shown in FIG. 6 is merely illustrative of one particular embodiment of such a moisture detection system 50. In FIG. 6, the zone 52 has a single strip sensor 62 connected between ground and the input 82 of microcontroller 30. The zone 54 has a single spot sensor 64 connected between ground and the input 84 of microcontroller 30. The zone 56, however, has a strip sensor 66, a spot sensor 68, and a strip sensor 70 all connected in series between ground and the input 86 of the microcontroller 30. Finally, the zone 58 has two strip sensors 72 and 74 connected in series between ground and the input 88 of the microcontroller 30. Because each of the inputs 82, 84, 86, and 88 are separate, the microcontroller 30 can determine which of the zones 52, 54, 56, or 58 has been invaded by moisture and that information can be stored and ultimately transmit it to a monitoring service in order to identify where investigation and remediation should be undertaken.

It should be emphasized that the above-described embodiments of the present invention are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

1. A moisture detector comprising:
a. a strip sensor comprising:
i. a strip substrate which when dry has a dry electrical resistance and when wet has a wet electrical resistance;
ii. conductor strips extending along the length of the strip substrate and electrically separated from each other by the strip substrate;
b. a microcontroller connected to the conductor strips and programmed to detect a change in the resistance of the strip substrate between the conductor strips as a result of the presence of moisture on the strip substrate.

2. The moisture detector of claim 1, wherein the strip substrate is an untreated polyester fabric.

3. The moisture detector of claim 1, wherein the strip substrate has a resistance that varies with the amount of moisture absorbed by the strip substrate.

4. The moisture detector of claim 3, wherein the microcontroller is programmed to identify a threshold resistance for the strip substrate that is indicative of the presence of moisture.

5. The moisture detector of claim 3, wherein the strip substrate has a dry resistance greater than 6 megohms.

6. A moisture detector comprising:
a. a spot sensor comprising:
i. a spot substrate which when dry has a dry electrical resistance and when wet has a wet electrical resistance;
ii. conductor electrodes embedded in the spot substrate and electrically separated from each other by the spot substrate;
b. a microcontroller connected to the conductor electrodes and programmed to detect a change in the resistance of the spot substrate between the conductor electrodes as a result of the presence of moisture.

7. The moisture detector of claim 6, wherein the spot substrate is dry wall.

8. The moisture detector of claim 6, wherein the spot substrate has a resistance that varies with the amount of moisture absorbed by the spot substrate.

9. The moisture detector of claim 8, wherein the microcontroller is programmed to identify a threshold resistance for the spot substrate that is indicative of the presence of moisture.

10. The moisture detector of claim 8, wherein the spot substrate has a dry resistance greater than 6 megohms.

11. A moisture detection system comprising:
a. a plurality of moisture sensors, each sensor comprising:
i. a substrate which when dry has a dry electrical resistance and when wet has a wet electrical resistance;
ii. conductors attached to and separated by the substrate;
b. a microcontroller connected to the conductors of the plurality of sensors and programmed to detect a change in the resistance of the substrate between the conductors as a result of the presence of moisture and to identify the moisture sensor of the plurality of moisture sensors where the presence of moisture exists.

12. The moisture detector of claim 11, wherein the substrate is an untreated polyester fabric.

13. The moisture detector of claim 11, wherein the substrate has a resistance that varies with the amount of moisture absorbed by the substrate.

14. The moisture detector of claim 13, wherein the microcontroller is programmed to identify a threshold resistance for the substrate that is indicative of the presence of moisture.

15. The moisture detector of claim 13, wherein the substrate has a dry resistance greater than 6 megohms.

16. A method for detecting moisture in a closed environment comprising the steps of:
a. placing a moisture sensor along a path where moisture may exist wherein the sensor comprises:
i. a substrate which when dry has a dry electrical resistance and when wet has a wet electrical resistance;
ii. conductors attached to and separated by the substrate;
b. connecting a microcontroller to the conductors and programming the microcontroller to detect a change in the resistance of the substrate between the conductors as a result of the presence of moisture.

17. The method of claim 16, wherein the substrate is an untreated polyester fabric.

18. The method of claim 16, wherein the substrate has a resistance that varies with the amount of moisture absorbed by the substrate.

19. The method of claim 18, wherein the microcontroller is programmed to identify a threshold resistance for the substrate that is indicative of the presence of moisture.

20. The method of claim 18, wherein the substrate has a dry resistance greater than 6 megohms.
